(19) United States
(12) Patent Application Publication
(10) Pub. No.: US 2012/0119163 A1
(43) Pub. Date: May 17, 2012

(54) SOLDERABLE POLYMER THICK FILM SILVER ELECTRODE COMPOSITION FOR USE IN THIN-FILM PHOTOVOLTAIC CELLS AND OTHER APPLICATIONS

(75) Inventor: JAY ROBERT DORFMAN, DURHAM, NC (US)

(73) Assignee: E. I. DU PONT DE NEMOURS AND COMPANY, Wilmington, DE (US)

(21) Appl. No.: 12/948,151

(22) Filed: Nov. 17, 2010

(51) Int. Cl. H01B 1/22; C23C 14/34; C23C 14/08; B05D 5/12

(52) U.S. Cl. 252/514; 427/74; 204/192.1

(57) ABSTRACT

The invention is directed to a polymer thick film silver composition comprising (a) a conductive silver powder; and (b) an organic medium comprising three different resins and organic solvent, wherein the ratio of the weight of the conductive silver powder to the total weight of the three different resins is between 5:1 and 45:1. The composition may be processed at a time and energy sufficient to remove all solvent.

The invention is further directed to a method of electrode grid and/or bus bar formation on thin-film photovoltaic cells using the composition and to cells formed from the method and the composition.

### FIELD OF THE INVENTION

The invention is directed to a solderable polymer thick film (PTF) silver conductor composition for use in thin-film photovoltaic cells. In one embodiment, the PTF silver composition is used as a screen-printed grid/bus bar on top of a transparent conductive oxide (TCO) such as indium tin oxide.

### TECHNICAL BACKGROUND OF THE INVENTION

Thin-film photovoltaic (PV) cells are usually characterized by a light-absorbing semiconductor such as amorphous silicon, copper indium gallium diselenide (CIGS), or cadmium telluride. This distinguishes them from the traditional crystalline silicon-based PV cells. Thin-film refers to the thickness of the semiconductor which is typically about 2 microns for the thin-film cells as opposed to 30-50 microns for crystalline silicon (c-silicon) cells. Another difference between thin-film and c-silicon PV cells is the temperature limitations involved. Thin-film cells must be processed at less than 200° C. as the semiconductor and/or the substrate used in thin-film cannot withstand high temperatures. The traditional c-silicon PV cells may be processed at temperatures up to 800° C. Thus, the use of a polymer thick film (PTF) silver composition as the front-side (sun side) electrode grid/bus bar is required. PTF compositions themselves are only stable up to approximately 200° C. Additionally, PTF compositions usually do not lend themselves to soldering as this is done at temperatures of 200 to 260° C. Further, most, if not all current PTF electrode compositions do not wet well with solder and do not possess good adhesion to the solar cell after soldering.

It is therefore a primary objective of this invention to produce a solderable PTF silver composition which adheres to the underlying substrate with reasonable adhesion even after soldering.

### SUMMARY OF THE INVENTION

The invention relates to a solderable polymer thick film composition comprising:
(a) a conductive silver powder; and
(b) an organic medium comprising three different resins and organic solvent,
   wherein the ratio of the weight of the conductive silver powder to the total weight of the three different resins is between 5:1 and 45:1.

The conductive silver powder is selected from the group consisting of silver metal powder, silver alloy powder and mixtures thereof. In one embodiment the silver metal powder is comprised of silver flakes.

In one embodiment, the three different resins are a phenoxy resin, a polyester resin and a phenolic resin

Based on the total weight of the composition, the silver flakes are 60 to 90 weight percent, the total weight of the three resins are 2 to 12 weight percent and the organic medium is 10 to 40 weight percent.

The composition may be processed at a time and temperature necessary to remove all solvent.

The invention is further directed to a method of electrode grid and/or bus bar formation on thin-film photovoltaic cells using the composition and to cells formed from the method and the composition.

### DETAILED DESCRIPTION OF INVENTION

The invention relates to a solderable polymer thick film silver composition for use in thin-film photovoltaic cells. It is typically used to improve the electrical efficiency of the cells and to make connection to the cell through soldering. A grid-like pattern and/or bus bars of the solderable polymer thick film silver composition are printed on top of a transparent conductive oxide.

Generally, a thick film composition comprises a functional phase that imparts appropriate electrically functional properties to the composition. The functional phase comprises electrically functional powders dispersed in an organic medium that acts as a carrier for the functional phase. The organic medium typically comprises polymer resin and an organic solvent. Generally, the composition is fired to burn out the organics and to impart the electrically functional properties. However, in the case of a polymer thick film, the polymer resin remains as an integral part of the composition after drying. Prior to firing, a processing requirement may include an optional heat treatment such as drying, curing, reflow, and others known to those skilled in the art of thick film technology.

The main components of the instant thick film conductor composition are a conductive powder dispersed in an organic medium, which includes polymer resin and solvent.

### A. Conductive Powder

In an embodiment, the conductive powders in the present thick film composition are silver conductor powders and are selected from the group comprising silver metal powder, silver metal alloy powder, or mixtures thereof. Various particle diameters and shapes of the metal powder are contemplated. In one embodiment, the conductive powder includes any shape silver powder, including spherical particles, flakes (rods, cones, plates), and mixtures thereof. In another embodiment, the conductive powder comprises silver flakes.

In one embodiment, the particle size distribution of the conductive powder is from 1 to 100 microns. In a further embodiment, the particle size distribution of the conductive powder is from 2 to 10 microns. In one embodiment, the surface area/weight ratio of the particles of the conductive powder is in the range of 0.1 to 2.0 m²/g. In another embodiment, the surface area/weight ratio of the particles of the conductive powder is in the range of 0.3 to 1.0 m²/g. In still another embodiment, the surface area/weight ratio of the particles of the conductive powder is in the range of 0.4-0.7 m²/g.

Furthermore, it is known that small amounts of other metals may be added to silver conductor compositions to improve the properties of the conductor. Some examples of such metals include: gold, silver, copper, nickel, aluminum, platinum, palladium, molybdenum, tungsten, tantalum, tin, indium, lanthanum, gadolinium, boron, ruthenium, cobalt, titanium, yttrium, europium, gallium, sulfur, zinc, silicon, magnesium, barium, cerium, strontium, lead, antimony, conductive carbon, and combinations thereof and others common in the art of thick film compositions. The additional metal(s) may comprise up to about 1.0 percent by weight of the total composition.

In one embodiment, the silver flakes are present at 60 to 90 wt % of the total weight of the composition. In another embodiment, the silver flakes are present at 65 to 85 wt % of the total weight of the composition. In still another embodiment, the silver flakes are present at 68 to 78 wt % of the total weight of the composition.

### B. Organic Medium

The powders are typically mixed with an organic medium, i.e. an organic vehicle, by mechanical mixing to form a paste like composition, called “paste”, having suitable consistency and rheology for printing. The organic medium is comprised of three different resins and an organic solvent.

The organic medium must be one in which the solids are dispersible with an adequate degree of stability. The rheological properties of the medium must be such that they lend good application properties to the composition. Such properties include dispersion of solids with an adequate degree of stability, good application of composition, appropriate viscosity, thixotropy, appropriate wettability of the substrate and the solids, a good drying rate, and a dried film strength sufficient to withstand rough handling.

The polymer resins required in one embodiment include a phenoxy resin, i.e., a polyhydroxyether resin, which allows high weight loading of silver flake and thus helps achieve both good adhesion to indium tin oxide (ITO) substrates and low contact resistivity, two critical properties for silver electrodes in thin-film photovoltaic cells. Another polymer resin required in this embodiment for high-temperature stability and thus adhesion after soldering is a phenolic resin. Yet a third required resin is a thermoplastic polyester resin which acts as a flux and helps to wet the silver with solder. In one such embodiment, the phenoxy resin is 0.1 to 1.0 wt % of the total weight of the composition. In another embodiment, the phenoxy resin is 0.2 to 0.9 wt % of the total weight of the composition. In still another embodiment, the phenoxy resin is 0.25 to 0.45 wt % of the total weight of the composition. In one embodiment, the phenolic resin is 0.3 to 3.0 weight percent of the total composition, while the polyester resin is 1.6 to 8.0 weight percent of the total composition.

Solvents suitable for use in the polymer thick film composition are recognized by one of skill in the art and include acetate and terpenes such as alpha- or beta-terpineol or mixtures thereof with other solvents such as kerosene, dibutylphthalate, butyl carbitol, butyl carbitol acetate, hexylene glycol and high boiling alcohols and alcohol esters. In one embodiment, the solvent is one or more components selected from the group consisting of: diethylene glycol ethyl ether acetate (carbitol acetate) and dibasic ester, and C-11 Ketone. In addition, volatile liquids for promoting rapid hardening after application on the substrate may be included in the organic vehicle. In many embodiments of the present invention, solvents such as glycol ethers, ketones, esters and other solvents of like boiling points (in the range of 180° C. to 250° C.), and mixtures thereof may be used. The preferred mediums are based on glycol ethers and β-terpineol. Various combinations of these and other solvents are formulated to obtain the viscosity and volatility requirements desired.

Although screen-printing is expected to be a common method for the deposition of polymer thick film silver, other conventional methods including stencil printing, syringe dispensing or other deposition or coating techniques may be utilized.

In one embodiment, the organic medium is present at 10 to 40 wt % of the total weight of the composition. In another embodiment, the organic medium is present at 25 to 35 wt % of the total weight of the composition. In still another embodiment, the organic medium is present at 28 to 32 wt % of the total weight of the composition.

### Application of Thick Films

The polymer thick film silver composition or “paste” is typically deposited on a substrate, such as sputtered polyester, that is impermeable to gases and moisture. The substrate can also be a sheet of flexible material. The flexible material can be an impermeable plastic such as polyester, e.g. polyethylene terephthalate, or a composite material made up of a combination of plastic sheet with optional metallic or dielectric layers deposited thereupon. In one embodiment, the substrate can be in the form of a thin-film photovoltaic cell, i.e., a build-up of layers with metalized, e.g., stainless steel, polyester followed by the semiconductor layer, e.g., CIGS, followed by a thin CdS layer, followed by sputtered indium tin oxide. The solderable polymer thick film silver composition is deposited onto the ITO on the front-side of the thin-film photovoltaic cell.

The deposition of the polymer thick film silver composition is performed preferably by screen printing, although other deposition techniques such as stencil printing, syringe dispensing or coating techniques can be utilized. In the case of screen-printing, the screen mesh size controls the thickness of deposited thick film.

The deposited thick film silver composition is dried, i.e., the solvent is evaporated, by exposure to heat for typically 15 to 30 min at 180° C., thus forming a thin-film photovoltaic cell with the dried silver composition on the front-side providing a silver metallization. After this drying or curing step, a solder ribbon whose composition is typically 62/36/2 Sn/Pb/Ag is attached to the printed silver metallization with a soldering gun heated to approximately 270° C.

### EXAMPLE

The present invention will be discussed in further detail by giving a practical example. The scope of the present invention, however, is not limited in any way by this practical example.

Adhesion to alumina was measured using an ASTM Tape method. A 600 grade tape was applied to a printed/dried pattern of PTF silver conductor composition. The tape was removed in a continuous fashion and the amount of silver ink material removed was estimated based upon an arbitrary scale of 1 to 5 with 5 representing no material removal, i.e. excellent adhesion.

### Example 1

### Comparative Experiments A & B

The PTF silver electrode paste was prepared by mixing silver flake with an average particle size of 5 μm and a range of particle size of 2 to 12 microns with an organic medium composed of polyhydroxyether resin, i.e., phenoxy resin (available from Phenoxy Associates, Inc), polyester resin (available from Shell Chemical) and phenolic resin (available from Georgia Pacific). The molecular weights of the resins were approximately 20,000. Solvents were used to dissolve the resins completely prior to adding the silver flake. Those solvents were carbitol acetate (available from Eastman Chemical) and DiBasic Esters-9 (available from Eastman Chemical Invista).

The composition of the polymer thick film silver composition of Example 1 was 70.00 wt % flaked silver and 30.00 wt % organic medium. The organic medium contained 0.25 wt % phenoxy resin, 6.88 wt. % polyester resin, 0.50 wt % phenolic resin and 22.37 wt % solvents. All wt % were based on the total weight of the composition.

This composition was mixed for 30 minutes on a planetary mixer. The composition was then transferred to a three-roll mill where it was subjected to two passes at 100 and 200 psi. At this point, the composition was used to screen print a silver grid pattern on top of alumina substrates. Using a 280 mesh stainless steel screen, a series of lines were printed, and the silver paste was dried at 170° C. for 30 min. in a forced air box oven. The resistivity was then measured as 15 milliohms/sq/mil. Soldering with 62/36/2 Sn/Pb/Ag resulted in good wetting and good adhesion to the substrate.

As a comparison, two standard compositions, each containing only one resin, were used in Comparative Experiments A and B. The standard composition used in Comparative Experiment A contained the polyester resin but not the other two resins used in Example 1. It was observed as having poor adhesion to the substrate after soldering. The standard composition used in Comparative Experiment B contained the phenoxy resin but not the other two resins used in Example 1. It showed a resistivity of approx. 15 mohm/sq/mil but would not solder and showed poor adhesion to the substrate.

The large improvement in solderability and adhesion for the silver conductor of Experiment 1, key properties for thin-film PV silver compositions, enables it to be used for most applications and improves PV cell efficiency. Note that Comparative Experiments A and B contained the same silver powder as Example 1. A summary of the results appears in Table 1

TABLE 1

| | Soldered Adhesion | |
|---|---|---|
| Silver Composition | to Alumina | Resistivity |
| Comp. Experiment A | 1 (poor) | 20 mohm/sq/mil |
| Comp. Experiment B | 1 (poor) | 15 mohm/sq/mil |
| Example 1 | 4 (good) | 15 mohm/sq/mil |

Scale for adhesion is 1 (complete loss of adhesion) to 5 (no material removal).

What is claimed is:

1. A composition comprising:
(a) a conductive silver powder; and
(b) an organic medium comprising three different resins and organic solvent,
wherein the ratio of the weight of said conductive silver powder to said total weight of said three different resins is between 5:1 and 45:1.

2. The composition of claim 1, wherein said conductive silver powder is selected from the group consisting of silver metal powder, silver metal alloy powder and mixtures thereof and said three different resins are a phenoxy resin, a polyester resin and a phenolic resin.

3. The composition of claim 2, said silver metal powder comprising silver flakes.

4. The composition of claim 3, wherein said organic solvent comprises one or more components selected from the group consisting of: diethylene glycol ethyl ether acetate and dibasic esters.

5. The composition of claim 3, wherein, based on the total weight of the composition, said silver flakes are 60 to 90 weight percent, the total weight of said three different resins are 2 to 12 weight percent and the organic medium is 10 to 40 weight percent.

6. A method of forming a silver grid on a thin-film photovoltaic cell, comprising the steps of:
(a) applying to the front-side of said thin-film photovoltaic cell a composition comprising:
(i) a conductive silver powder; and
(ii) an organic medium comprising three different resins and organic solvent,
wherein the ratio of the weight of said conductive silver powder to said total weight of said three different resins is between 5:1 and 45:1; and
(b) drying said composition.

7. The method of claim 6, wherein said conductive silver powder is selected from the group consisting of silver metal powder, silver metal alloy powder and mixtures thereof and said three different resins are a phenoxy resin, a polyester resin and a phenolic resin.

8. The method of claim 7, said silver metal powder comprising silver flakes.

9. The method of claim 8, wherein said organic solvent comprises one or more components selected from the group consisting of: diethylene glycol ethyl ether acetate and dibasic esters.

10. The method of claim 8, wherein, based on the total weight of the composition, said silver flakes are 60 to 90 weight percent, the total weight of said three different resins are 2 to 12 weight percent and the organic medium is 10 to 40 weight percent.

11. The method of claim 6, wherein the front-side of said thin-film photovoltaic cell is sputtered with indium tin oxide.

12. A thin-film photovoltaic cell comprising a silver grid line and/or bus bars comprising the dried composition of claim 1.

13. A thin-film photovoltaic cell comprising a silver grid line and/or bus bars comprising the dried composition of claim 2

14. A thin-film photovoltaic cell comprising a silver grid line and/or bus bars comprising the dried composition of claim 3.

15. A thin-film photovoltaic cell comprising a silver grid line and/or bus bars comprising the dried composition of claim 4

16. A thin-film photovoltaic cell comprising a silver grid line and/or bus bars comprising the dried composition of claim 5.

17. A thin-film photovoltaic cell formed by the method of claim 6.

18. A thin-film photovoltaic cell formed by the method of claim 7.

19. A thin-film photovoltaic cell formed by the method of claim 8

20. A thin-film photovoltaic cell formed by the method of claim 10.
